(19) United States
(12) Patent Application Publication
(10) Pub. No.: US 2025/0072147 A1
(43) Pub. Date: Feb. 27, 2025

(54) MICRO-LENS ARRAY FOR OBTAINING THREE-DIMENSIONAL IMAGE AND METHOD OF MANUFACTURING THE MICRO-LENS ARRAY

(71) Applicant: ELECTRONICS AND TELECOMMUNICATIONS RESEARCH INSTITUTE, Daejeon (KR)

(72) Inventors: Chihoon KIM, Daejeon (KR); Mun Seob LEE, Daejeon (KR); Sang Yun KIM, Daejeon (KR)

(73) Assignee: ELECTRONICS AND TELECOMMUNICATIONS RESEARCH INSTITUTE, Daejeon (KR)

(21) Appl. No.: 18/788,443

(22) Filed: Jul. 30, 2024

(30) Foreign Application Priority Data
Aug. 23, 2023 (KR) 10-2023-0110526

(51) Int. Cl. H01L 27/146; G02B 5/30

(52) U.S. Cl. CPC H01L 27/14627; G02B 5/3058

(57) ABSTRACT

A micro-lens array is provided. The micro-lens array includes a transparent substrate, a plurality of polarizers disposed on the transparent substrate, a passivation layer covering the plurality of polarizers, and a plurality of micro-lenses disposed on the passivation layer, wherein light reflected to an object passes through the transparent substrate, and then, is polarized based on a plurality of different polarization orientations formed by the plurality of polarizers and is incident on the plurality of micro-lenses.

### CROSS-REFERENCE TO RELATED APPLICATIONS

This application claims the benefit of the Korean Patent Application No. 10-2023-0110526 filed on Aug. 23, 2023, which is hereby incorporated by reference as if fully set forth herein.

### BACKGROUND

### Field of the Invention

The present invention relates to plenoptic image processing technology for obtaining a three-dimensional image.

### Discussion of the Related Art

Three-dimensional (3D) images such as plenoptic or light-field images provide information about light which travels in an arbitrary direction in a space. Plenoptic images may be obtained from a sensor (camera) sensor structure or a micro-lens array structure, and in terms of the application and cost of small plenoptic images, the micro-lens array structure is advantageous.

General micro-lens arrays for obtaining a plenoptic image does not include a filter such as a polarizer, which transmits only a light wave in a specific direction. Because the general micro-lens arrays including no polarizer transmit a light wave in various directions, a plenoptic image captured by the general micro-lens array is an unpolarized image which is identically seen with respect to all angles.

Because the polarizer transmits only a light wave in a specific direction, when the polarizer is applied to a micro-lens array, there is an advantage where a polarization image including characteristic information (for example, surface roughness and a geometrical structure of an object) about the object incapable of being discovered with eyes of a user may be obtained. Also, the diffusion reflection of an object surface and a reduction in resolution of an image caused by a low contrast may be improved by the polarizer. Accordingly, it is urgently required to develop micro-lens arrays including a polarizer.

### SUMMARY

An aspect of the present invention is directed to providing a micro-lens array including a polarizer and a method of manufacturing the micro-lens array.

To achieve these and other advantages and in accordance with the purpose of the invention, as embodied and broadly described herein, there is provided a micro-lens array including a transparent substrate; a plurality of polarizers disposed on the transparent substrate; a passivation layer covering the plurality of polarizers; and a plurality of micro-lenses disposed on the passivation layer, wherein light reflected to an object passes through the transparent substrate, and then, is polarized based on a plurality of different polarization orientations formed by the plurality of polarizers and is incident on the plurality of micro-lenses.

In an embodiment, the plurality of polarizers may include a first polarizer and a second polarizer adjacent to the first polarizer, the plurality of micro-lenses may include a first micro-lens corresponding to the first polarizer and a second micro-lens corresponding to the second polarizer, and the light reflected to the object may be polarized based on a first polarization orientation of the first polarizer and may be incident on the first micro-lens, and may be polarized based on a second polarization orientation of the second polarizer and may be incident on the second micro-lens.

In an embodiment, each of the plurality of polarizers may include a metal grid pattern having a rectilinear shape oriented based on one of the plurality of different polarization orientations.

In an embodiment, the plurality of polarizers may be divided into a plurality of sets, each of the plurality of sets may include four polarizers arranged in a rectangular shape, and a first polarizer of the four polarizers may form a horizontal polarization orientation of the plurality of different polarization orientations, a second polarizer may form a polarization orientation inclined by 45 degrees with respect to the horizontal polarization orientation, a third polarizer may form a polarization orientation inclined by −45 degrees with respect to the horizontal polarization orientation, and a fourth polarizer may form a vertical polarization orientation inclined by 90 degrees with respect to the horizontal polarization orientation.

In an embodiment, the plurality of micro-lenses may be arranged in a rectangular array structure or a hexagonal array structure.

In another aspect of the present invention, there is provided a method of manufacturing a micro-lens array, the method including: a step of forming polarizers forming a plurality of different polarization orientations on a transparent substrate; a step of forming a passivation layer covering the polarizers; and a step of forming semispherical micro-lenses on the passivation layer.

In an embodiment, the step of forming the polarizers may include a step of forming the polarizers by using an electron beam evaporation process.

In an embodiment, each of the polarizers may include a metal grid pattern having a rectilinear shape.

In an embodiment, a material of the metal grid pattern may include a gold (Au)-based material, an aluminum (Al)-based material, a titanium (Ti)-based material, a chromium (Cr)-based material, or a combination of at least two materials thereof.

In an embodiment, the step of forming the semispherical micro-lenses may include: a step of coating photoresist layers on the passivation layer; a step of patterning the photoresist layer based on cylindrical patterns by using a photolithography process; and a step of processing the semispherical micro-lenses based on the cylindrical patterns by using a thermal reflow process.

In another aspect of the present invention, there is provided a micro-lens array including: a transparent substrate; a plurality of polarizers disposed on the transparent substrate; a passivation layer covering the plurality of polarizers; and a plurality of micro-lenses disposed on the passivation layer, wherein the micro-lens array further includes an optical absorption structure configured to prevent crosstalk where light passing through the transparent substrate is polarized by the plurality of polarizers, and then, the polarized light is incident on another micro-lens instead of a target micro-lens, and the optical absorption structure includes: a first metal layer disposed on the passivation layer; an insulating layer disposed on the first metal layer; and a second metal layer disposed between the plurality of micro-lenses disposed on the insulating layer.

In an embodiment, light reflected to an object may pass through the transparent substrate, and then, may be polarized based on a plurality of different polarization orientations formed by the plurality of polarizers and may be incident on the plurality of micro-lenses through the optical absorption structure.

In an embodiment, each of the plurality of polarizers may include a metal grid pattern having a rectilinear shape oriented based on one of the plurality of different polarization orientations.

In an embodiment, the light passing through the transparent substrate may be polarized based on one of the plurality of different polarization orientations by the plurality of polarizers, and electric field components of the polarized light incident on the other micro-lens among electric field components of the polarized light passing through the first metal layer may be trapped in the insulating layer between the first metal layer and the second metal layer.

In an embodiment, a material of the first metal layer may include gold (Au), silver (Ag), aluminum (Al), or an alloy including at least two thereof.

In an embodiment, a material of the insulating layer may include silicon dioxide (SiO₂) or aluminum oxide (Al₂O₃).

In an embodiment, a material of the second metal layer may include a composition including at least two of germanium (Ge), graphene oxide, aluminum (Al), gold (Au), silver (Ag), or chromium (Cr).

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a plan view of a micro-lens array according to an embodiment of the present invention.

FIG. 2 is a cross-sectional view taken along line I-I′ of FIG. 1.

FIG. 3 is a diagram for describing a polarization orientation corresponding to each micro-lens based on a polarizer of FIG. 2 in a 4×4 micro-lens array according to an embodiment of the present invention.

FIGS. 4 to 9 are diagrams for describing a method of manufacturing a micro-lens array according to an embodiment of the present invention and are cross-sectional views taken along line I-I′ of FIG. 1.

FIG. 10 is a block diagram of a plenoptic imaging system (device) including the micro-lens array of FIGS. 1 and 2 according to an embodiment of the present invention.

FIG. 11 is a flowchart for describing a processing process of the plenoptic imaging system of FIG. 10.

FIG. 12 is a cross-sectional view of a micro-lens array according to another embodiment of the present invention.

FIGS. 13 to 20 are cross-sectional views for describing a method of manufacturing the micro-lens array of FIG. 12.

### DETAILED DESCRIPTION OF THE INVENTION

Hereinafter, exemplary embodiments of the present invention will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to one of ordinary skill in the art. In the drawings, the dimensions of layers and regions are exaggerated or reduced for clarity of illustration. For example, a dimension and thickness of each element in the drawings are arbitrarily illustrated for clarity, and thus, embodiments of the present invention are not limited thereto.

Unless otherwise defined, all terms (including technical and scientific terms) used herein may be used as a meaning capable of being commonly understood by one of ordinary skill in the art. Also, terms defined in dictionaries used generally are not ideally or excessively construed unless clearly and specially defined.

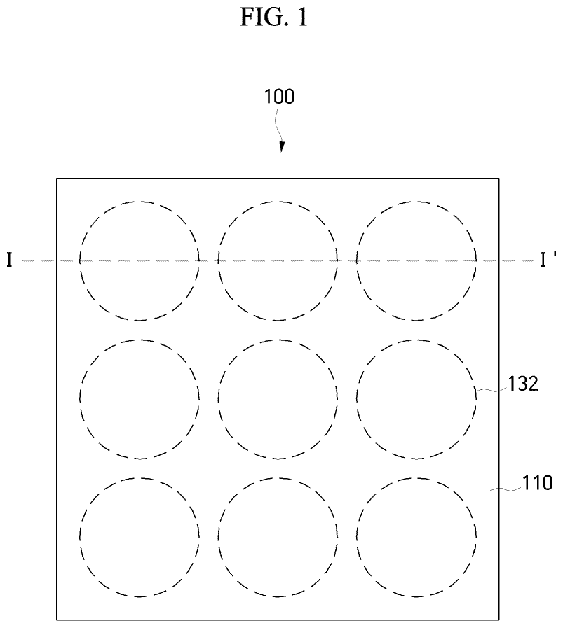

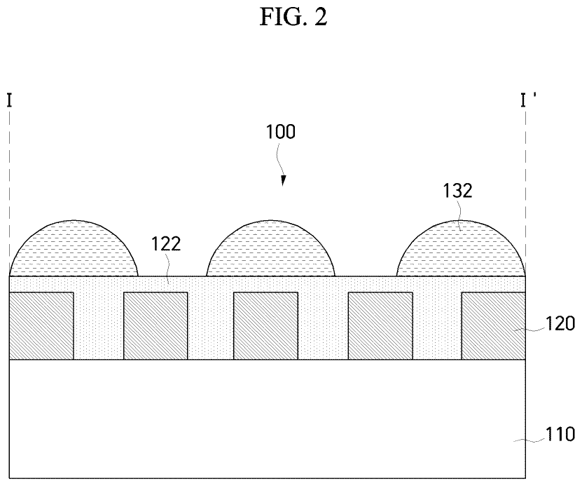

FIG. 1 is a plan view of a micro-lens array 100 according to an embodiment of the present invention, and FIG. 2 is a cross-sectional view taken along line I-I′ of FIG. 1.

Referring to FIGS. 1 and 2, the micro-lens array 100 may include a plurality of micro-lenses 132 disposed on a transparent substrate 110 and a polarizer 120 between the transparent substrate 110 and the plurality of micro-lenses 132.

The transparent substrate 110 may be, for example, a silicon substrate, a glass substrate, or a quartz substrate.

The plurality of micro-lenses 132 may be continuously arranged in a first direction (for example, an x-axis direction) and a second direction (for example, a y-axis direction) intersecting with the first direction on the substrate 110. Accordingly, as illustrated in FIG. 1, the plurality of micro-lenses 132 may be arranged in a rectangular array structure. However, the present invention is not limited thereto, and the plurality of micro-lenses 132 may be arranged in various array structures, and for example, may be arranged in a hexagonal array structure.

The micro-lens 132 may have a hemispherical shape. The micro-lens 132 may be a positive or negative photoresist. Herein, it may be assumed that the micro-lens 132 is a positive photoresist. A material of the photoresist may use a polymer-based material, and for example, may use acrylate or polyimide.

A polarizer 120 disposed between the transparent substrate 110 and the micro-lenses 132 may induce the linear polarization of light incident through the micro-lenses 132. That is, the polarizer 120 may filter only a light wave in a specific direction in light incident through the transparent substrate 110, based on the linear polarization.

To induce linear polarization, the polarizer 120 may include a metal grid pattern having a rectilinear shape oriented in the specific direction. At this time, a plurality of polarizers 120 may form a plurality of different polarization orientations offset by the metal grid pattern. Based on each polarization orientation, lights passing through the micro-lenses 132 may be filtered based on a polarization orientation of the polarizer 120, and filtered light may be sampled by a photodetector device (for example, a complementary metal-oxide semiconductor (CMOS) sensor).

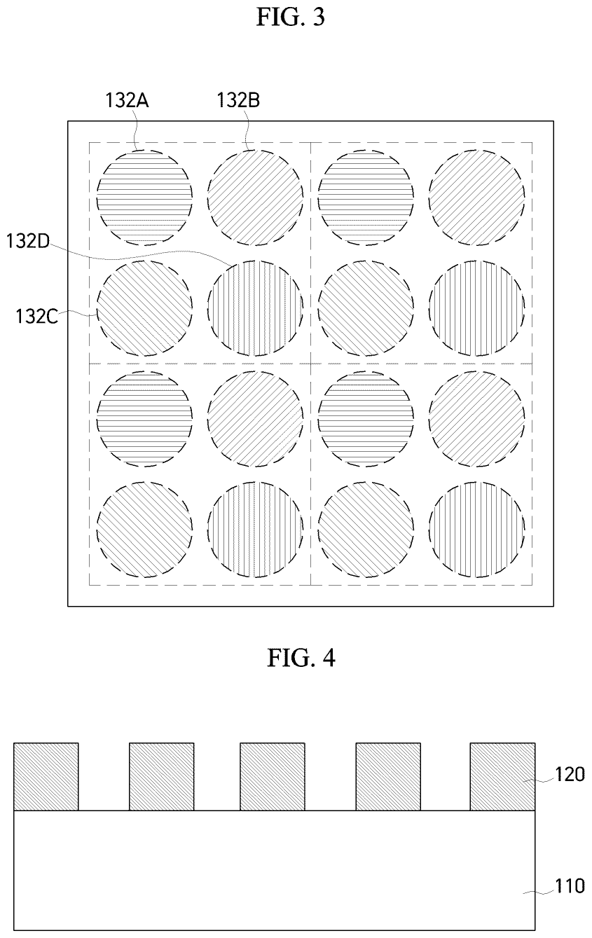

FIG. 3 is a diagram for describing a polarization orientation corresponding to each micro-lens based on a polarizer of FIG. 2 in a 4×4 micro-lens array according to an embodiment of the present invention.

As illustrated in FIG. 3, lights passing through the micro-lenses 132 may be polarized in different directions, based on a polarization orientation of the polarizer 120 disposed under each micro-lens 132. In an embodiment of the present invention, a total of four polarization orientations may be configured as one set.

For example, a polarizer corresponding to a first micro-lens 132A may form a horizontal polarization orientation to filter light passing through the first micro-lens 132A, a polarizer corresponding to a second micro-lens 132B disposed in a right direction of the first micro-lens 132A may form a polarization orientation inclined by about 45 degrees with respect to the horizontal polarization orientation to filter light passing through the second micro-lens 132B, and a polarizer corresponding to a third micro-lens 132C disposed in a downward direction of the first micro-lens 132A may form a polarization orientation inclined by about −45 degrees with respect to the horizontal polarization orientation to filter light passing through the third micro-lens 132C. Also, a polarizer corresponding to a fourth micro-lens 132D disposed in a diagonal direction of the first micro-lens 132A may form a vertical polarization orientation inclined by about 90 degrees with respect to the horizontal polarization orientation to filter light passing through the fourth micro-lens 132D. That is, a polarizer corresponding to one micro-lens and a polarizer corresponding to another micro-lens adjacent to the one micro-lens may include a metal grid pattern oriented in different directions.

A diameter of each micro-lens and a size of a clear aperture may differ based on a pixel size of a photodetector device or a size of an image filtered by a polarizer. Also, an image filtered based on a polarization orientation of each polarizer may include different features on the same object. Also, a linear interval, a period, and a height of a metal grid of a polarizer may be determined based on a diffraction characteristic of light. Also, a transmittance of a polarizer may be determined based on an extinction ratio which is a significant performance indicator.

Four images formed based on four different polarization orientations illustrated in FIG. 3 may be configured as one image set, but are not limited thereto and images filtered by the same polarization orientation may be configured as one image set. Such a process may be selectively determined based on a surface characteristic of an object.

Furthermore, in FIG. 2, a reference numeral 122 may refer to a passivation layer which protects the polarizer 120 disposed on the transparent substrate 110.

FIGS. 4 to 9 are diagrams for describing a method of manufacturing a micro-lens array according to an embodiment of the present invention and are cross-sectional views taken along line I-I′ of FIG. 1.

Referring to FIG. 4, a process of depositing the polarizers 120 having a rectilinear-shape metal grid pattern patterned or oriented in a specific direction (for example, four polarization orientations) on the transparent substrate 110 may be performed.

The transparent substrate 110 may include one of silicon, glass, and quartz. A material of the metal grid pattern may use a gold (Au)-based material, an aluminum (Al)-based material, a titanium (Ti)-based material, a chromium (Cr)-based material, or a combination of at least two materials thereof.

A deposition process of the polarizer 120 may include, for example, an electron beam evaporation process using an electron beam, but is not limited thereto and the deposition process may include all processes enabling the deposition of a metal material without a limitation of kind.

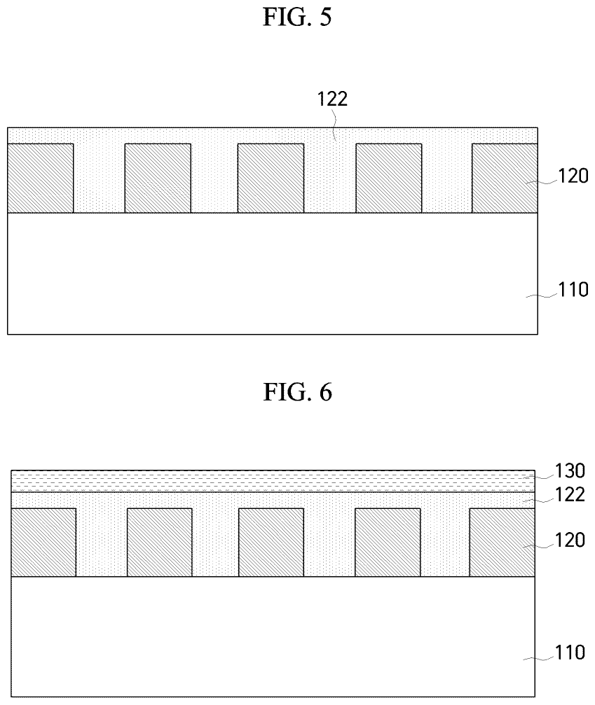

Subsequently, referring to FIG. 5, a process of depositing a passivation layer 122 covering the polarizers 120 may be performed. The passivation layer 122 may protect the polarizers 120. A material of the passivation layer 122 may include an oxide silicon-based material (for example, silicon dioxide (SiO₂)). A deposition process of the passivation layer 122 may include, for example, a plasma enhanced chemical vapor deposition (PECVD).

Subsequently, referring to FIG. 6, a process of coating a photoresist layer 130 on the passivation layer 122 may be performed. The coating process of the photoresist layer 130 may include, for example, a roll coating process, a spin coating process, a slit die coating process, and an inkjet printing process.

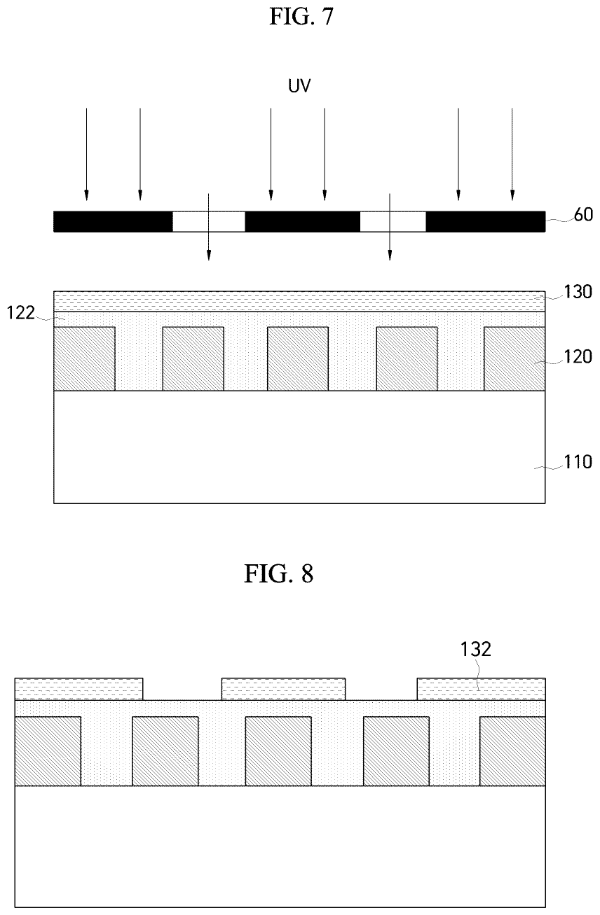

Subsequently, referring to FIGS. 7 and 8, a process of patterning the photoresist layer 130 to form patterns 132 having a cylindrical shape may be performed. The process of forming the patterns 132 may include, for example, a photolithography process of exposing and developing the photoresist layer 130 by using a photo mask 60.

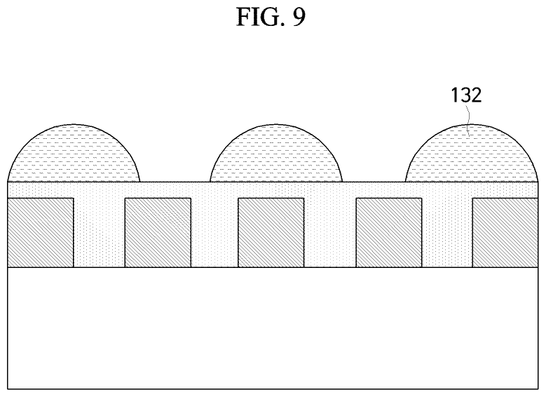

Subsequently, referring to FIG. 9, a process of processing the patterns 132 having a cylindrical shape to form the micro-lenses 132 having a semispherical shape may be performed. The process of forming the micro-lenses 132 having a semispherical shape from the patterns 132 having a cylindrical shape may include, for example, a thermal treatment process such as a reflow process.

An array structure of the micro-lenses 132 may be a rectangular or hexagonal array structure. In this case, a fill factor of the micro-lens 132 may relatively higher appear in the hexagonal array structure and an interval between lenses may also be dense, and thus, in forming the micro-lenses 132 having the hexagonal array structure, a minimum interval should be maintained within a range which does not affect a process of forming an adjacent lens.

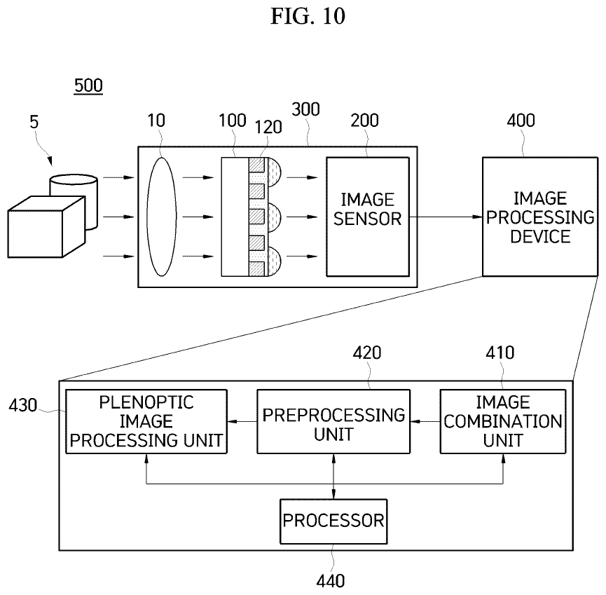

FIG. 10 is a block diagram of a plenoptic imaging system (device) 500 including the micro-lens array of FIGS. 1 and 2 according to an embodiment of the present invention.

Referring to FIG. 10, the plenoptic imaging system 500 may include an image obtainment device 300 and an image processing device 400. The image obtainment device 300 may obtain a plurality of polarization images polarized based on a plurality of different polarization orientations (FIG. 3) from light reflected to an object 5. The image processing device 400 may process the plurality of polarization images obtained from the image obtainment device 300 to reconfigure as a three-dimensional (3D) image (a plenoptic image) having a high contrast and a high resolution.

In detail, the image obtainment device 300 may be implemented with a camera, an infrared camera, a microscope, or a telescope. The image obtainment device 300 may include an objective lens 10, a micro-lens array 100, and an image sensor 200. The objective lens 10, the micro-lens array 100, and the image sensor 200 may be packaged as one module with being spaced apart from one another by a certain distance.

The light reflected to the object 5 may pass through the objective lens 10 and may then be incident on the micro-lens array 100. Light passing through the objective lens 10 may be polarized based on a plurality of different polarization orientations (FIG. 3) by the polarizer 120 included in the micro-lens array 100. For example, the light passing through the objective lens 10 may be polarized based on four polarization orientations (FIG. 3) oriented at a 45-degree interval. The image sensor 200 may obtain a plurality of polarization images respectively corresponding to the plurality of different polarization orientations illustrated in FIG. 3 from light polarized based on the plurality of different polarization orientations (FIG. 3). The image sensor 200 may include, for example, a complementary metal oxide semiconductor (CMOS) sensor.

The image processing device 400 may reconfigure the plurality of polarization images, obtained by the image obtainment device 300 and polarized by the plurality of different polarization orientations, as a 3D image (a plenoptic image), and to this end, may include an image combination unit 410, a preprocessing unit 420, a plenoptic image processing unit 430, and a processor 440.

The image combination unit 410 may combine (synthesize) the plurality of polarization images obtained by the image obtainment device 300 and polarized by the plurality of different polarization orientations. To combine (synthesize) the plurality of polarization images, for example, an image synthesis algorithm may be used.

The preprocessing unit 420 may preprocess an image combined (synthesized) by the image combination unit 410 to increase a resolution of a combined (synthesized) image. Polarization images filtered by the polarizer 120 may be obtained for each of different polarization orientations. Because the polarization image is obtained for each polarization orientation, a resolution of each image may be reduced in a process of dividing an image of an object 5 for each polarization orientation. Therefore, a resolution of the image combined by the image combination unit 410 may also be reduced. The preprocessing unit 420 may increase a reduction in resolution of an image. Various image preprocessing algorithms may be used for increasing a resolution of a combined image. The image preprocessing algorithm may use, for example, a very-deep super-resolution (VDSR) neural network.

The plenoptic image processing unit 430 may process an image preprocessed by the preprocessing unit 420 to generate a 3D image such as a plenoptic image. For example, light field rendering may be used for generating the plenoptic image.

The image combination unit 410, the preprocessing unit 420, and the plenoptic image processing unit 430 may each be a hardware module or a software module, and in a case which is implemented as a software module, the processor 440 may control executions of the image combination unit 410, the preprocessing unit 420, and the plenoptic image processing unit 430, which are each implemented as a software module. The processor 440 may include at least one central processing unit (CPU), at least one graphics processing unit (GPU), and at least one memory which provides a stored instruction to the CPU or the GPU. In this context, the image processing device 400 may be a computing device such as a desktop computer or a laptop computer.

As described above, the plenoptic imaging system 500 may obtain polarization images by using the image obtainment device, and then, may generate a 3D plenoptic image through image preprocessing and plenoptic image processing on the polarization images.

Moreover, a micro-lens manufactured for generating the 3D plenoptic image may combine polarization images obtained through a plurality of different polarization orientations so as to enable observation of a surface characteristic of an object, and thus, a resolution and a contrast of the 3D plenoptic image may be enhanced.

The plenoptic imaging system 500 may be applied to extensive application fields such as general cameras, medical cameras, bio-recognition cameras, automatic inspection cameras, mobile cameras, special-purpose cameras (for example, infrared cameras), microscopes, and telescopes.

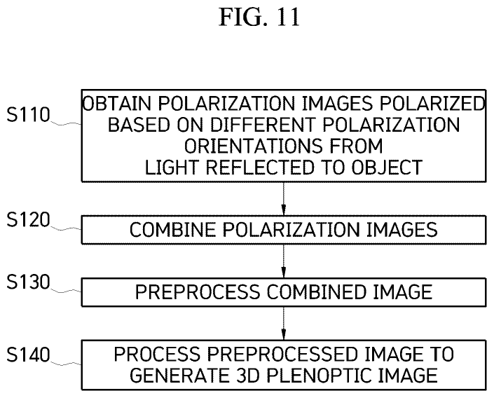

FIG. 11 is a flowchart for describing a processing process of the plenoptic imaging system of FIG. 10.

Referring to FIG. 11, first, in step S110, in the image obtainment device 300 including the micro-lens array 100 including the polarizer 120, a process of obtaining a plurality of polarization images, polarized based on a plurality of different polarization orientations, from light reflected to the object 5 may be performed.

Subsequently, in step S120, in the image combination unit 410 of the image processing device 400, a process of combining (synthesizing) the plurality of polarization images may be performed. Here, for example, an image synthesis algorithm may be used for combining (synthesizing) the plurality of polarization images.

Subsequently, in step S130, in the preprocessing unit 420, a process of preprocessing the image combined (synthesized) by the image combination unit 410 may be performed for improving a reduction in resolution of an image in a process of dividing an image of the object 5 for each polarization orientation. The image preprocessing algorithm may use, for example, a very-deep super-resolution (VDSR) neural network.

Subsequently, in step S140, in the plenoptic image processing unit 430, a process of processing the image preprocessed by the preprocessing unit 420 to generate a 3D plenoptic image may be performed. For example, light field rendering may be used for generating the 3D plenoptic image.

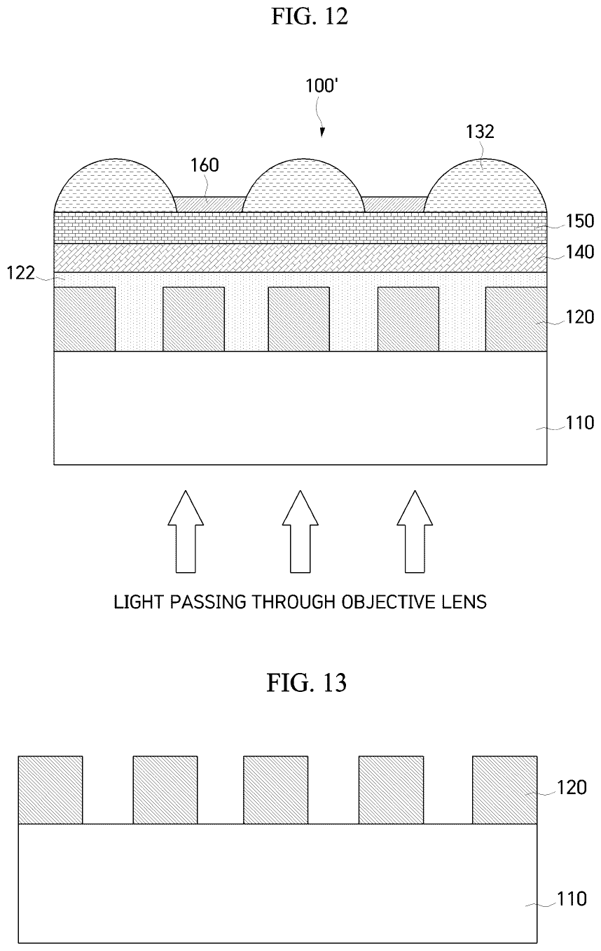

FIG. 12 is a cross-sectional view of a micro-lens array 100′ according to another embodiment of the present invention.

Referring to FIG. 12, the micro-lens array 100′ according to another embodiment of the present invention may have a difference with the micro-lens array of FIG. 2 in that crosstalk is prevented where light (light reflected to an object) passing through a transparent substrate (110 of FIG. 2) is polarized by the polarizer 120, and then, the polarized light is incident on another micro-lens instead of a target micro-lens.

To prevent such crosstalk, the micro-lens array 100′ according to another embodiment of the present invention may be configured to further include an optical absorption structure configured as a metal layer-insulating layer-metal layer structure.

In detail, the optical absorption structure may include a first metal layer 140, an insulating layer 150, and a second metal layer 160. The first metal layer 140 may be disposed on the passivation layer 122 which protects the polarizer 120, and the insulating layer 150 may be disposed on the first metal layer 140. Also, the second metal layer 160 may be disposed between the micro-lenses 132 disposed on the insulating layer 150.

Light passing through the transparent substrate 110 may be polarized based on a plurality of different polarization orientations by the polarizer 120, and the polarized light may pass through the first metal layer 140. Electric field components of the polarized light incident on another micro-lens among electric field components of the polarized light passing through the first metal layer 140 may be trapped in the insulating layer 150 between the first metal layer 140 and the second metal layer 160. Therefore, crosstalk may be prevented where light (light reflected to an object) passing through the transparent substrate 110 is polarized by the polarizer 120, and then, the polarized light is incident on another micro-lens instead of a target micro-lens. Accordingly, a contrast and a resolution of an image (plenotpic image) may be enhanced, and thus, a modulation transfer function (MTF) of a micro-lens may be improved.

The first metal layer 140 may be a thin film layer having a plate shape, and a thickness thereof may be 10 nm or less. A material of the first metal layer 140 may include Au, Ag, Al, or an alloy including at least two thereof. The insulating layer 150 may fundamentally function as a visible light transmission layer, and moreover, may trap an electric field component of light polarized by the polarizer 120. A thickness of the insulating layer 150 may be 50 nm or less. A material of the insulating layer 150 may include, for example, silicon dioxide (SiO₂) or aluminum oxide (Al₂O₃). The second metal layer 160 may function as a wall which traps an electric field component of light, passing through the first metal layer 140, in the insulating layer 150 along with the first metal layer 140. That is, the second metal layer 160 may function as a reflective layer for light passing through the first metal layer 140. A thickness of the second metal layer 160 may be 30 nm or less, and a material of the second metal layer 160 may include germanium (Ge), graphene oxide, aluminum (Al), gold (Au), silver (Ag), or chromium (Cr).

FIGS. 13 to 20 are cross-sectional views for describing a method of manufacturing the micro-lens array of FIG. 12.

Referring to FIG. 13, a process of depositing the polarizers 120 having a rectilinear-shape metal grid pattern patterned or oriented in a specific direction (for example, four polarization orientations) on the transparent substrate 110 may be performed. The transparent substrate 110 may include one of silicon, glass, and quartz. A material of the metal grid pattern may use a gold (Au)-based material, an aluminum (Al)-based material, a titanium (Ti)-based material, a chromium (Cr)-based material, or a combination of at least two materials thereof.

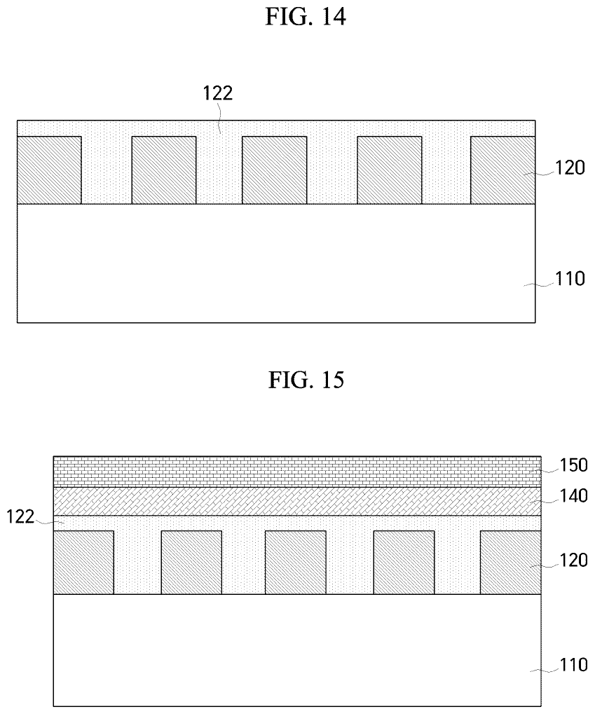

Subsequently, referring to FIG. 14, a process of depositing a passivation layer 122 covering the polarizers 120 may be performed. The passivation layer 122 may protect the polarizers 120. A material of the passivation layer 122 may include an oxide silicon-based material (for example, silicon dioxide (SiO₂)). A deposition process of the passivation layer 122 may include, for example, a plasma enhanced chemical vapor deposition (PECVD).

Subsequently, referring to FIG. 15, a process of sequentially depositing the first metal layer 140 and the insulating layer 150, configuring the optical absorption structure, on the passivation layer 122 may be performed. A deposition process of the first metal layer 140 and the insulating layer 150 may include a PECVD process. The first metal layer 140 may be a thin film layer having a plate shape, and a thickness thereof may be 10 nm or less. A material of the first metal layer 140 may include Au, Ag, Al, or an alloy including at least two thereof. A material of the insulating layer 150 may include, for example, SiO₂ or Al₂O₃.

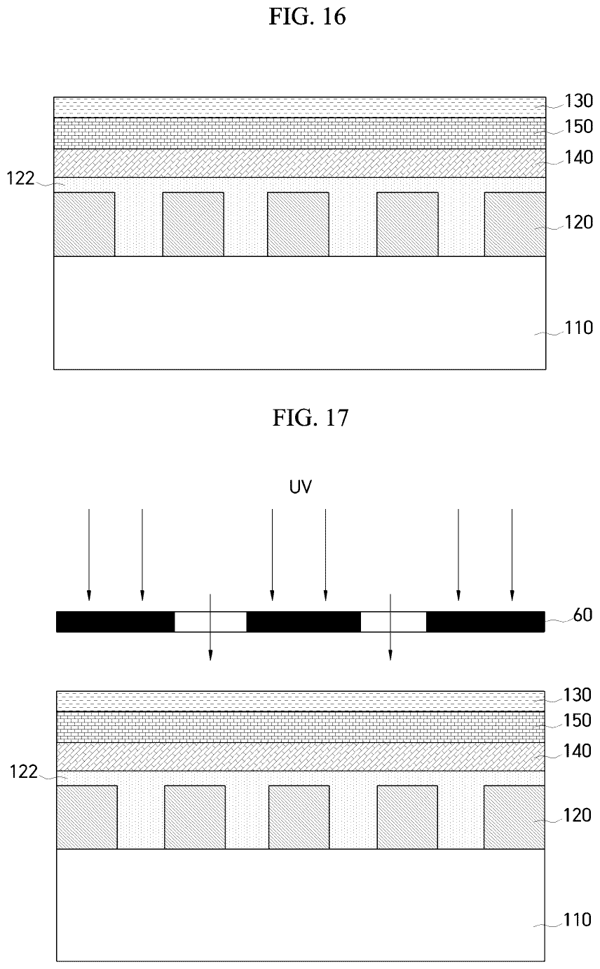

Subsequently, referring to FIG. 16, a process of coating the photoresist layer 130 on the insulating layer 150 may be performed. The coating process of the photoresist layer 130 may include, for example, a roll coating process, a spin coating process, a slit die coating process, and an inkjet printing process.

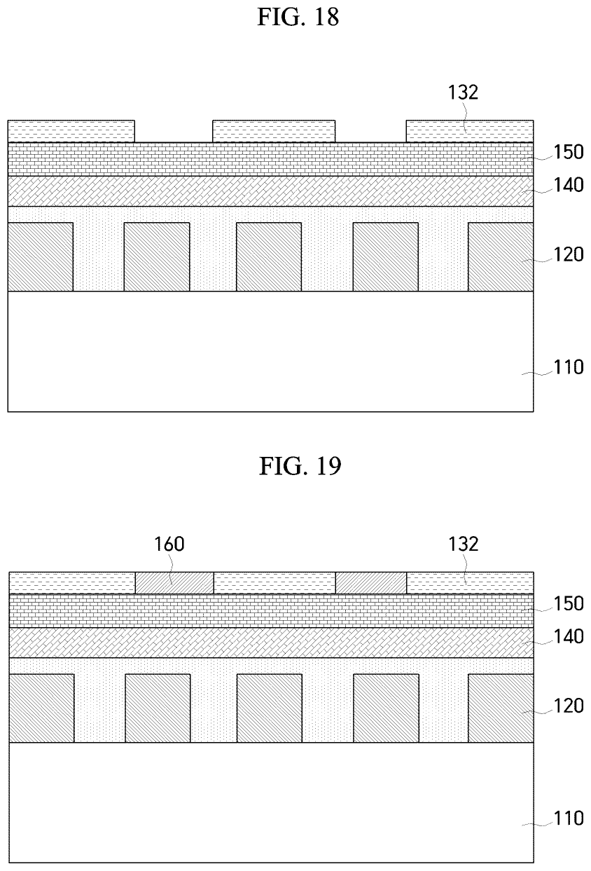

Subsequently, referring to FIGS. 17 and 18, a process of patterning the photoresist layer 130 to form the patterns 132 having a cylindrical shape may be performed. The process of forming the patterns 132 may include, for example, a photolithography process of exposing and developing the photoresist layer 130 by using the photo mask 60.

Subsequently, referring to FIG. 19, a process of forming the second metal layer 160 configuring the optical absorption structure between the patterns 132 on the insulating layer 150 may be performed. The process of forming the second metal layer 160 may include a deposition process and a photolithography process. In FIG. 19, a photo mask needed in the photolithography process of forming the second metal layer 160 is not illustrated.

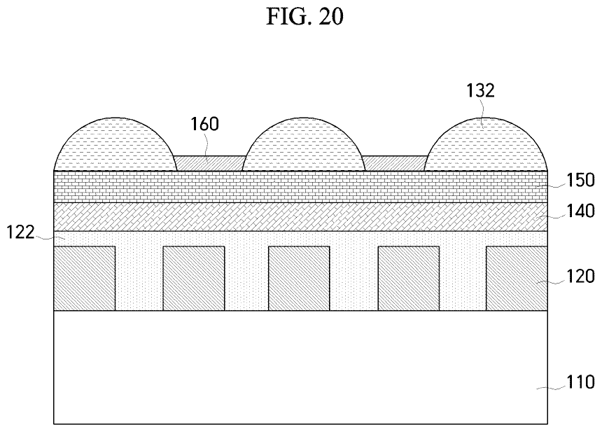

Subsequently, referring to FIG. 20, a process of processing the patterns 132 having a cylindrical shape to form the micro-lenses 132 having a semispherical shape may be performed. The process of forming the micro-lenses 132 having a semispherical shape may include, for example, a thermal treatment process such as a reflow process.

According to the embodiments of the present invention, the micro-lens array for obtaining a 3D image (for example, a plenoptic image) may include the polarizer which transmits only a light wave in a specific direction, thereby improving a reduction in resolution of a 3D image caused by a low contrast and diffusion reflection occurring in an object surface.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A micro-lens array comprising:
a transparent substrate;
a plurality of polarizers disposed on the transparent substrate;
a passivation layer covering the plurality of polarizers; and
a plurality of micro-lenses disposed on the passivation layer,
wherein light reflected to an object passes through the transparent substrate, and then, is polarized based on a plurality of different polarization orientations formed by the plurality of polarizers and is incident on the plurality of micro-lenses.

2. The micro-lens array of claim 1, wherein the plurality of polarizers comprise a first polarizer and a second polarizer adjacent to the first polarizer,
the plurality of micro-lenses comprise a first micro-lens corresponding to the first polarizer and a second micro-lens corresponding to the second polarizer, and
the light reflected to the object is polarized based on a first polarization orientation of the first polarizer and is incident on the first micro-lens, and is polarized based on a second polarization orientation of the second polarizer and is incident on the second micro-lens.

3. The micro-lens array of claim 1, wherein each of the plurality of polarizers comprises a metal grid pattern having a rectilinear shape oriented based on one of the plurality of different polarization orientations.

4. The micro-lens array of claim 1, wherein the plurality of polarizers are divided into a plurality of sets,
each of the plurality of sets comprises four polarizers arranged in a rectangular shape, and
a first polarizer of the four polarizers forms a horizontal polarization orientation of the plurality of different polarization orientations, a second polarizer forms a polarization orientation inclined by 45 degrees with respect to the horizontal polarization orientation, a third polarizer forms a polarization orientation inclined by −45 degrees with respect to the horizontal polarization orientation, and a fourth polarizer forms a vertical polarization orientation inclined by 90 degrees with respect to the horizontal polarization orientation.

5. The micro-lens array of claim 1, wherein the plurality of micro-lenses are arranged in a rectangular array structure or a hexagonal array structure.

6. A method of manufacturing a micro-lens array, the method comprising:
a step of forming polarizers forming a plurality of different polarization orientations on a transparent substrate;
a step of forming a passivation layer covering the polarizers; and
a step of forming semispherical micro-lenses on the passivation layer.

7. The method of claim 6, wherein the step of forming the polarizers comprises a step of forming the polarizers by using an electron beam evaporation process.

8. The method of claim 6, wherein each of the polarizers comprises a metal grid pattern having a rectilinear shape.

9. The method of claim 8, wherein a material of the metal grid pattern comprises a gold (Au)-based material, an aluminum (Al)-based material, a titanium (Ti)-based material, a chromium (Cr)-based material, or a combination of at least two materials thereof.

10. The method of claim 6, wherein the step of forming the semispherical micro-lenses comprises:
a step of coating photoresist layers on the passivation layer;
a step of patterning the photoresist layer based on cylindrical patterns by using a photolithography process; and
a step of processing the semispherical micro-lenses based on the cylindrical patterns by using a thermal reflow process.

11. A micro-lens array comprising:
a transparent substrate;
a plurality of polarizers disposed on the transparent substrate;
a passivation layer covering the plurality of polarizers; and
a plurality of micro-lenses disposed on the passivation layer,
wherein the micro-lens array further comprises an optical absorption structure configured to prevent crosstalk where light passing through the transparent substrate is polarized by the plurality of polarizers, and then, the polarized light is incident on another micro-lens instead of a target micro-lens, and
the optical absorption structure comprises:
a first metal layer disposed on the passivation layer;
an insulating layer disposed on the first metal layer; and
a second metal layer disposed between the plurality of micro-lenses disposed on the insulating layer.

12. The micro-lens array of claim 11, wherein light reflected to an object passes through the transparent substrate, and then, is polarized based on a plurality of different polarization orientations formed by the plurality of polarizers and is incident on the plurality of micro-lenses through the optical absorption structure.

13. The micro-lens array of claim 11, wherein each of the plurality of polarizers comprises a metal grid pattern having a rectilinear shape oriented based on one of the plurality of different polarization orientations.

14. The micro-lens array of claim 11, wherein the light passing through the transparent substrate is polarized based on one of the plurality of different polarization orientations by the plurality of polarizers, and electric field components of the polarized light incident on the other micro-lens among electric field components of the polarized light passing through the first metal layer are trapped in the insulating layer between the first metal layer and the second metal layer.

15. The micro-lens array of claim 11, wherein a material of the first metal layer comprises gold (Au), silver (Ag), aluminum (Al), or an alloy including at least two thereof.

16. The micro-lens array of claim 11, wherein a material of the insulating layer comprises silicon dioxide (SiO₂) or aluminum oxide (Al₂O₃).

17. The micro-lens array of claim 11, wherein a material of the second metal layer comprises a composition including at least two of germanium (Ge), graphene oxide, aluminum (Al), gold (Au), silver (Ag), or chromium (Cr).
